(19) United States
(12) Patent Application Publication
(10) Pub. No.: US 2021/0028709 A1
(43) Pub. Date: Jan. 28, 2021

(54) A LOW DIFFERENTIAL SWITCHING REGULATOR

(71) Applicant: Cummins Ltd, London (GB)

(72) Inventors: Avinash Waman Narwekar, Pine, Maharashtra (IN); Atul Ninu Narkhede, Pine, Maharashtra (IN)

(21) Appl. No.: 16/492,953

(22) PCT Filed: Jul. 24, 2019
(86) PCT No.: PCT/IN2019/050539

§ 371 Date: Sep. 11, 2019

(51) Int. Cl. H02M 3/335; G01R 19/165

(52) U.S. Cl. CPC H02M 3/33576; H02M 2001/0025; G01R 19/16538

(57) ABSTRACT

The invention provides a Low Differential Switching Regulator. The regulator includes a switching buck converter. The switching buck converter generates a desired differential voltage from an applied input voltage. A voltage source is coupled to the switching buck converter to supply the input voltage and a PWM controller is coupled to the switching buck converter in feedback configuration. Further, an output load is connected in series with the switching buck converter and a voltage sensor is connected to the output load to generate a signal proportional to the output is voltage. The low differential switching regulation is achieved when the output voltage is marginally different from the input voltage.

### FIELD OF INVENTION

The invention generally relates to the field of voltage regulation and particularly to a low differential switching regulator.

### BACKGROUND

Voltage regulators are generally used in electronic circuits to get a desired output voltage level by using electronic components. Usually two kinds of DC-DC voltage regulators are used to derive desired output at the load. One type of voltage regulator is the Low Dropout Linear Regulator (LDO), which regulates the output voltage, when the output voltage is marginally lower than the input voltage. The disadvantage of LDO is excessive power dissipation due to series connection of elements like resistors or transistors, which results in low efficiency. Another type of voltage regulator known in the art is the Switching Regulator that is used when the output voltage is significantly different from the input voltage. Switching Regulators are efficient because the series element is either fully conducting or switched off thereby dissipating lesser power. The main deficiency associated with the Switching Regulator is significant switching losses in the switching device such as a MOSFET, which handles the full input voltage and current. Here the power loss is proportional to the product of voltage and current, which are both high. Further, the power loss in the filter at the output of the Switching Regulator is directly related to the power output of the regulator. To power devices or applications where output voltage is very close to input voltage, a more efficient voltage regulator is required. The said normal regulators are incapable of giving highly regulated desired output voltage with very low power loss, due to their deficiencies as mentioned herein above. Hence, there is a need for a switching regulator that gives a desired output voltage with very low power loss, when output voltage is marginally different from the input voltage.

### BRIEF DESCRIPTION OF DRAWINGS

So that the manner in which the recited features of the invention can be understood in detail, some of the embodiments are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a block diagram of a Low Differential Switching Regulator, according to an embodiment of the invention.

FIG. 2 shows a schematic representation of a Low Differential Switching Regulator, according to an embodiment of the invention.

### SUMMARY OF THE INVENTION

One aspect of the invention provides a Low Differential Switching Regulator. The regulator includes a switching buck converter. The switching buck converter generates a desired differential voltage from an applied input voltage. A voltage source is coupled to the switching buck converter to supply the input voltage and a PWM controller is coupled to the switching buck converter in feedback configuration. Further, an output load is connected in series with the switching buck converter and a voltage sensor is connected to the output load to generate a signal proportional to the output voltage. The low differential switching regulation is achieved when the output voltage is marginally different from the input voltage.

### DETAILED DESCRIPTION OF THE INVENTION

Various embodiments of the invention provide a Low Differential Switching Regulator.

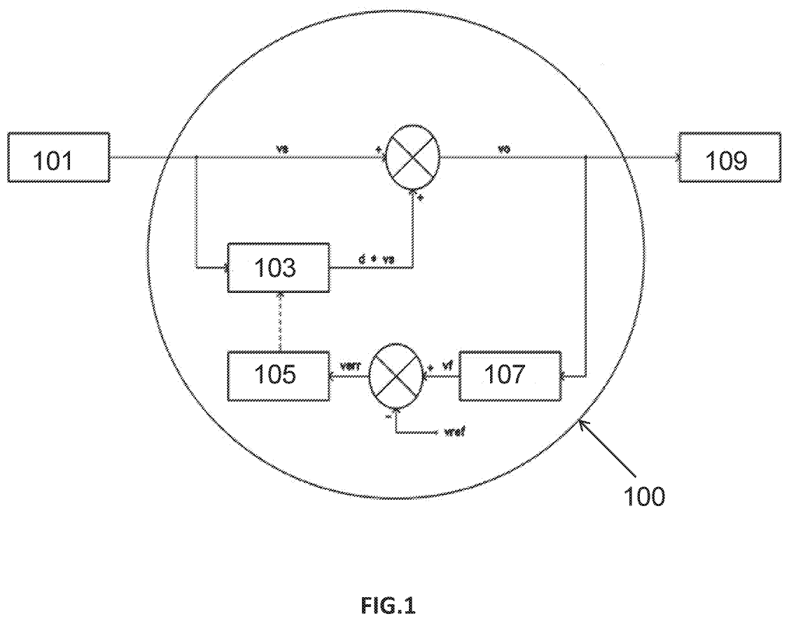

FIG. 1 shows a block diagram of Low Differential Switching Regulator 100, according to an embodiment of the invention. The Low Differential Switching Regulator 100 has a voltage source 101, a switching buck converter 103, a voltage sensor 105, a PWM controller 107 and an output load 109.

The voltage source 101 is connected to the switching buck converter 103 to supply input voltage. The voltage source 101 described herein includes but is not limited to a battery, a solar photo-voltaic cell and a high-voltage DC-microgrid. In one example of the invention, the voltage source 101 is a battery. The sum of the voltages of the voltage source 101 and the output voltage of the switching buck converter 103 are used to drive the output load 109. The voltage sensor 105 is connected to the output load 109 to sense the output voltage, and it generates a signal proportional to the output voltage. The output of the voltage sensor 105 is compared with a reference voltage to generate an error voltage, which is fed to the PWM controller 107. The PWM controller gives feedback to the switching buck converter 103, to control the duty cycle. The output load 109 is connected in series with the voltage source 101 and the switching buck converter 103.

The voltage source 101 supplies voltage to the switching buck converter 103. The output of the switching buck converter 103 is ‘d*vs’ where ‘d’ is the duty cycle and ‘vs’ is the voltage of the voltage source. The sum of the voltages of the voltage source 101 and the output of the switching buck converter 103 drives the output load 109. The output voltage at the output load 109 is sensed by the voltage sensor 105 and that generates a signal proportional to the output voltage. The proportional output voltage is compared with a reference voltage ‘vref’ to generate an error signal ‘verr’ that is fed to the PWM controller 107. The PWM controller 107 alters the duty cycle of the switching buck converter 103 in accordance with the error signal to generate a low differential voltage. Further, the PWM controller 107 controls the magnitude of the differential voltage. Based on the value of the differential voltage generated by the switching buck converter 103, a small voltage is added to or subtracted from the input voltage to obtain a desired output voltage.

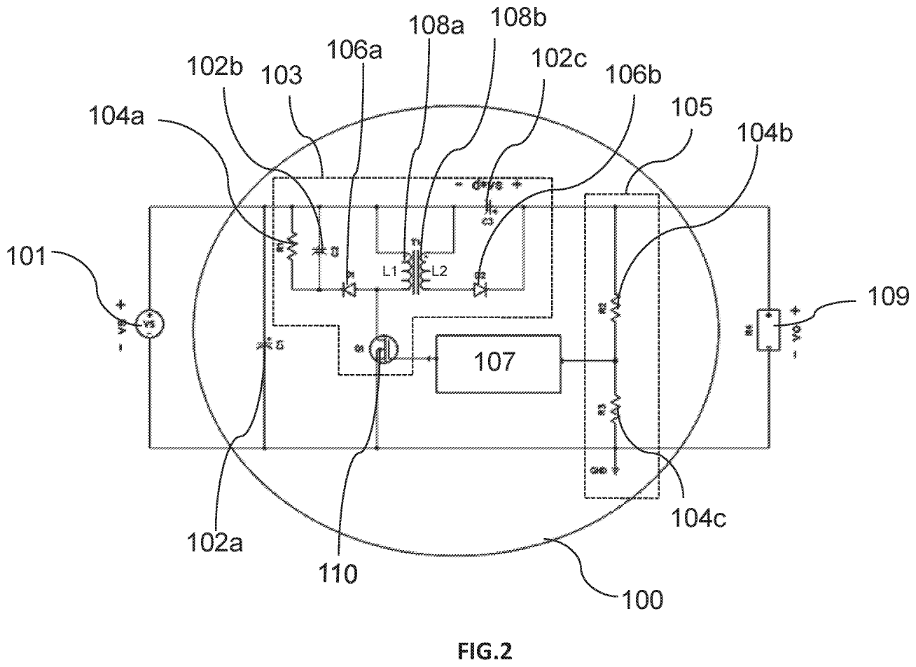

FIG. 2 shows a schematic representation of Low Differential Switching Regulator 100, according to an embodiment of the invention. The voltage source 101 is connected to the switching buck converter 103 through parallelly connected filter capacitor 102a. The switching buck converter 103 includes a primary winding 108a, a secondary winding 108b, a MOSFET switch 110, a rectifier diode 106b, and a filter capacitor 102c. Resistor 104a, capacitor 102b and diode 106a form a snubber circuit that protects the MOSFET switch 110 from excessive voltages. The MOSFET switch 110 is turned on and off at a high frequency, with a duty cycle that is controlled by the PWM controller 107. The output of the switching buck converter is the voltage across capacitor 102c. The input voltage source 101 and the capacitor 102c are connected in series to generate the total output that drives the output load 109. Resistors 104b and 104c form the voltage sensor 105 whose output is fed to the PWM controller 107.

The overall efficiency (nₗ) of the Low Differential Switching Regulator is given by,

nₗ=1−[d*(1−n_{b})/(n_{b}+d)]

where, nₗ is the efficiency of the Low Differential Switching Regulator, d is the duty cycle of the switching buck converter, n_{b} is the efficiency of the switching buck converter.

In one example of the invention, if the desired output is 5% more than the input, ‘d’ would be 0.05. Efficiency of the switching buck converter is typically 90%, i.e. n_{b}=0.90. So, the above expression becomes,

$${n}_{l} = 1 - [ 0. 0 {5}^{⋆} ( 1 - 0.90 ) \text{/} ( 0.90 + 0.05 ) ] = 1 - 0.0053 = 0.9947 = 99.47 \%$$

This reveals that, the Low Differential Switching Regulator possesses a very high efficiency which results in a very low power loss.

By comparison, the efficiency of an LDC is

n=(1−Ig/Ii)*(1−Vh/Vi)

where Ig is the Ground current, Ii is the input current, Vh is the headroom voltage, Vi is the input voltage. Typically, Ig/Ii is 0.01, and Vh/Vi is 0.1. So, the above expression becomes

n=(1−0.01)*(1−0.1)=0.99*0.9=0.891=89.1%

The efficiency of a Switching Regulator is also typically in the range 85% to 90%.

Thus, the efficiency of a Low Differential Switching Regulator is much higher than that of an LDO or a conventional Switching Regulator.

Hence, the invention as described herein and as illustrated in the accompanying drawings provides a low differential voltage regulator, when the output voltage is marginally different from the input voltage. Since the output voltage is only marginally different from the input voltage, the differential voltage handled by the Low Differential Switching Regulator is very low, resulting in very low power losses. For situations when output voltage is marginally different from the input voltage, the Low Differential Switching Regulator is particularly useful. The invention finds its applications to control the power flow across interconnected DC grids, to provide a stable supply voltage to appliances driven by a high-voltage DC-microgrid, to adjust the output voltage of serially connected solar panels to maximize the power output of the entire string and to obtain fixed output voltage with minimum power loss in battery driven systems.

The foregoing description of the invention has been set merely to illustrate the invention and is not intended to be limiting. Since modifications of the disclosed embodiments incorporating the scope and substance of the invention may occur to person skilled in the art, the invention should be construed to include everything within the scope of the appended claims and equivalents thereof.

We claim:

1. A low differential switching regulator, the regulator comprising:
a switching buck converter, wherein the switching buck converter generates a desired differential voltage from an applied input voltage;
a voltage source coupled to the switching buck converter to supply the input voltage;
a PWM controller coupled to the switching buck converter in feedback configuration;
an output load connected in series with the switching buck converter; and
a voltage sensor connected to the output load to generate a signal proportional to the output voltage;
wherein the low differential switching regulation is achieved when the output voltage is marginally different from the input voltage.

2. The regulator as claimed in claim 1, wherein the typical efficiency of low differential switching regulator is 99.47%.

3. The regulator as claimed in claim 1, wherein the switching buck converter adds or subtracts a small voltage from the input voltage to provide the desired output voltage.

4. The regulator as claimed in claim 1, wherein the small voltage to be added or subtracted is generated by the switching buck converter.

5. The regulator as claimed in claim 1, wherein the PWM controller controls the magnitude of the differential voltage by comparing the output voltage with a reference voltage.

6. The regulator as claimed in claim 1, wherein the PWM controller alters the duty cycle of the switching buck converter to maintain the output voltage at a desired level.
